(19) United States
(12) Patent Application Publication
(10) Pub. No.: US 2003/0102991 A1
(43) Pub. Date: Jun. 5, 2003

(54) Digital sample frequency converter

(76) Inventor: Laurent Pasquier, Asnieres-Sur-Seine (FR)

Correspondence Address: U.S. Philips Corporation, 580 White Plains Road, Tarrytown, NY, 10591, US

(21) Appl. No.: 10/294,531

(22) Filed: Nov. 14, 2002

(30) Foreign Application Priority Data
Nov. 20, 2001 (FR) 0115001

(51) Int. Cl. H03M 7/00

(52) U.S. Cl. 341/61

(57) ABSTRACT

The present invention relates to a converter for converting a digital input signal (1) into a digital output signal (3) using a set of filtering coefficients. The converter comprises filtering means effecting a filtering function and producing the set of filtering coefficients from phase differences (2) between a sample of the digital output signal and samples of the digital input signal, the filtering function being defined by a set of polynomials. The filtering means also comprise a memory (52) for storing coefficients of the polynomials, and means (53) of calculating the set of filtering coefficients from coefficients of the polynomials and phase differences. Such a converter allows a large number of format conversions, while having limited memory resources.

### FIELD OF THE INVENTION

The present invention relates to a converter for converting a digital input signal into a digital output signal using a set of filtering coefficients, said converter comprising filter means able to form a filter function and to supply a filtering coefficient from a phase difference between a sample of the digital output signal and a sample of the digital input signal.

It also relates to a method of converting the digital input signal into a digital output signal.

It finds in particular its application in digital television receivers, for example during a conversion of the image format.

### BACKGROUND OF THE INVENTION

In many video systems, it is often necessary to effect a conversion of a digital input signal from a first sample frequency to a second sample frequency, according to the image format required by the receiving device. Such a conversion results in a magnification or reduction of the original image corresponding to an up-sampling or a down-sampling of said image.

In a conventional all-digital system, the conversion is carried out in three main steps. In a first step, an interpolation filter makes it possible to up-sample the digital input signal sampled at a frequency f1 to obtain an intermediate signal sampled at a frequency f3 such that f3=k.f2, k being an integer and f2 being the sample frequency required at the output of the converter. In a second step, a low-pass filter is applied to the intermediate signal in order to guarantee the Shannon theorem. Finally, during a third step, a decimation of the signal thus filtered is carried out to obtain an output signal sampled at the frequency f2.

These three steps can advantageously be implemented by a finite pulse response filter FPR with a polyphase structure. Such a filter with four coefficients or taps is described in FIGS. 1 and 2, respectively in direct operating mode and inverse operating mode. It comprises a convolver (12) able to produce a digital output signal (3) sampled at a frequency f2 from a digital input signal (1) sampled at a frequency f1 and a set of four filtering coefficients. Said set of filtering coefficients comes from a memory (11) containing a set of filtering coefficients for each phase difference between a sample of the digital output signal and a sample of the digital input signal. Calculation means, not shown here, also calculate the phase difference between a sample of the digital output signal and a sample of the digital input signal. In direct operating mode, the convolver comprises shift registers (121) able to shift a sample, and a summing device SUM (123) able to add together the products of a shifted sample and a filtering coefficient said products coming from the multipliers (122). In inverse operating mode, the convolver comprises four multipliers (122) able to effect the product of a filtering coefficient and a current sample of the digital input signal. The output of a first multiplier is connected to the input of a first shift register (121). A first adder (124) effects a sum of the output of the first shift register and a second multiplier and supplies said sum to a second shift register. A second adder effects a sum of the output of the second shift register and a third multiplier and supplies this sum to a third shift register. A third adder effects a sum of the output of the third shift register and a fourth multiplier and produces a sample of the digital output signal (3).

Canadian patent granted under the number CA 2,144,111 describes a conversion method as described in the introductory paragraph. This method uses a finite impulse response filter FIR with a polyphase structure with the same structure as that described previously, and comprises in particular a memory bank containing sets of filtering coefficients. These sets of filtering coefficients are precalculated for various phase difference values, the phase difference number possible being limited by the size of the memory bank. However, the more different phase difference values the filter has, the more conversions with different formats it can carry out. In other words, the performance of a polyphase filter is closely linked to the size of its memory. The result therefore is that a polyphase filter as defined in the state of the art is capable of managing only a limited number of format conversions, which limits its performance.

### SUMMARY OF THE INVENTION

It is an object of the present invention to propose a method and device for converting a digital input signal into a digital output signal, which has a better performance, making it possible in particular to manage a larger number of phase difference values, and therefore a larger number of format conversions, while having limited memory resources.

To this end, the converter according to the invention is characterized in that the filtering function is defined by a set of polynomials, and in that the filtering means comprise a memory able to store coefficients of the polynomials, and calculation means able to calculate the set of filtering coefficients from the coefficients of the polynomials and the phase differences between a sample of the digital output signal and samples of the digital input signal.

Thus the converter according to the invention has a memory in which only the coefficients of the polynomials partly approximating the filtering function are stored. In the case of a filtering function approximated by 4 third degree polynomials, only 16 coefficients are stored. The calculation means then calculate the filtering coefficients from the coefficients of the polynomials and the phase differences between the input samples and the output sample. This calculation is particularly simple to implement in the case of polynomials.

In addition, the present invention has the advantage of allowing in a simple fashion format conversions with a variable scale factor. Such conversions are particularly useful for representing images in perspective.

### BRIEF DESCRIPTION OF THE DRAWINGS

The invention will be further described with reference to examples of embodiment shown in the drawings to which, however, the invention is not restricted.

FIG. 1 is a diagram depicting the functioning in direct mode of a polyphase filter with 4 coefficients according to the state of the art,

FIG. 2 is a diagram depicting the functioning in inverse mode of a polyphase filter with 4 coefficients according to the state of the art,

FIG. 3a is a diagram depicting a circuit for calculating the phase difference between a sample of the digital output signal and a sample of the digital input signal,

FIG. 3b illustrates the result of such a calculation in the case of a scale factor equal to ⅘,

FIG. 4 illustrates a low-pass filtering function in the spatial domain and its partial approximation by polynomials, and

FIG. 5 is a diagram depicting the functioning in direct mode of a filter with 4 coefficients according to the invention.

### DESCRIPTION OF PREFERRED EMBODIMENT(S)

The present invention relates to a converter for converting a digital input signal into a digital output signal, comprising a filter of the polyphase structuretape. It has been developed in the case of a video data format conversion, the digital signal comprising samples of the pixel type but remains applicable to other types of data such as audio data for example. In the case of video data, the pixel values which are filtered are, for example, the luminance or chrominance data.

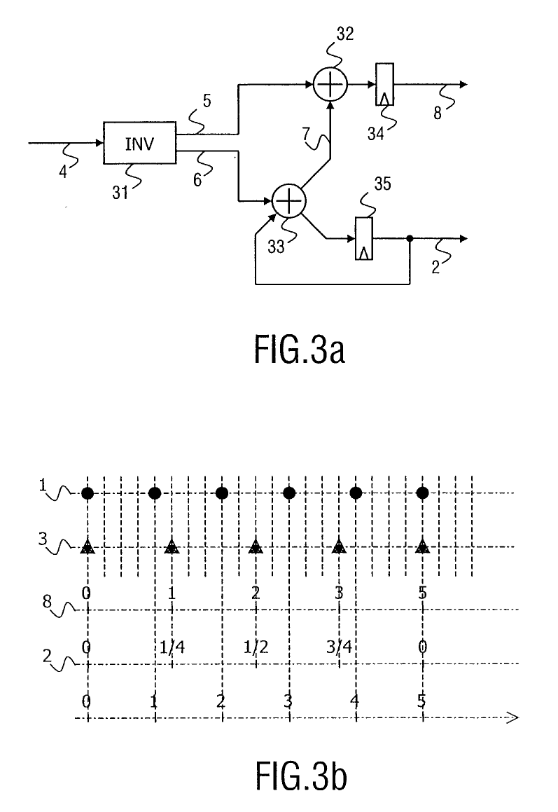

The term polyphase indicates a periodic representation of the phase differences between a sample of the digital input signal, a pixel in the case of a video signal, and a sample of the digital output signal. These phase differences are calculated according to a scale factor or zoom factor z according to the principle in FIG. 3a.

The calculation circuit in said Figure is able to receive the scale factor z (4), and comprises inversion and separation means (31) able to invert the scale factor and to produce an integer part (5) and a fractional part (6) of the inverted scale factor 1/z. The integer part is delivered to a first input of a first adder (32) and the fractional part is delivered to a first input of a second adder (33). The first adder is also able to receive at a second input a carry (7) coming from the second adder and to produce the sum of the carry and of the integer part to a first shift register (34), itself responsible for producing an integer position (8) of the pixel in a line or column of the image. The output of the second adder is connected to a second shift register (35), the latter being responsible for producing a fractional position of the pixel in a line or column of the image, this fractional position corresponding to the phase difference (2). The fractional position is also connected to a second input of the second adder.

The example in FIG. 3b illustrates the functioning of the calculation circuit in the case of a zoom factor equal to ⅘, therefore corresponding to a ratio of the frequency f2 of the digital output signal to the frequency f1 of the digital input signal equal to ⅘. The first pixels of the digital input and output signals are merged. The inverted scale factor is equal to 1.25, corresponding to an integer part of 1 and a fractional part of ¼. The phase difference being initially 0, the carry is equal to 0 and the integer position is consequently 1 and the phase difference ¼. Recommencing the operation, a periodic set of phase differences is obtained equal to {0 ¼ ½ ¾}.

The converter according to the invention comprises filtering means adapted to effect a filtering function and to produce a set of filtering coefficients for a given phase difference among the periodic set of phase differences. As seen previously, the filtering coefficients are complex to generate, and it is advantageous to have sets of precalculated filtering coefficients, the sum of the filtering coefficients in a set being equal to 1. Thus the filtering coefficients are generated only once. A conventional polyphase filter is able to manage 64 phase differences, which may prove markedly insufficient, in particular in the video domain where a user may wish to carry out a fine adjustment of the size of an image on a video monitor, a television receiver for example. For example, if a user wishes an image consisting of lines of 640 pixels to become an image consisting of lines of 641 pixels, 641 different phase differences are necessary, which requires the storage of 641 sets of coefficients, and therefore entails a large size for the memory of the polyphase filter.

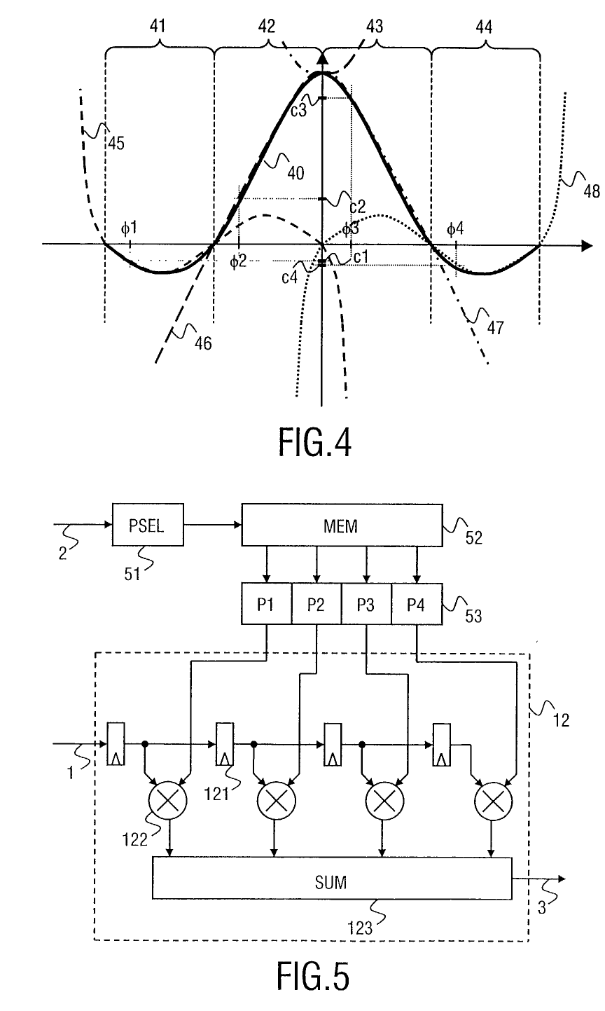

This is why the filtering function of the converter according to the invention is approximated by a set of polynomials. FIG. 4 illustrates a low-pass filtering function in the spatial domain and its approximation in parts by polynomials. The present invention is however not limited to this type of filtering function and can be applied, for example, to filtering functions where the frequencies f1 of the input signal and f2 of the output signal are equal, or to high-pass filtering functions for a segmentation. The filtering function (40) is here a bounded cardinal sine sinc (x)=sin (πx)/(πx). The drawback of the non-bounded filtering function sinc ( ) is that all the input pixels contribute to the reconstruction of a current output pixel. The low-pass filtering function is approximated by a set of polynomials called “splines”. In the example in FIG. 4, these polynomials are 4 in number, each polynomial (45 to 48) corresponding to an interval of 1 pixel (41 to 44).

Only the coefficients of the polynomials partly approximating the filtering function, that is to say 16 coefficients in our example, are then kept in memory and the filtering coefficients are calculated on the fly from coefficients of the polynomials whatever the value of the phase difference. Third order polynomials are preferably used and an approximation of the filtering function by a set of polynomials generally proves sufficient, but it will be clear to a person skilled in the art that other polynomials and sets of polynomials are also possible.

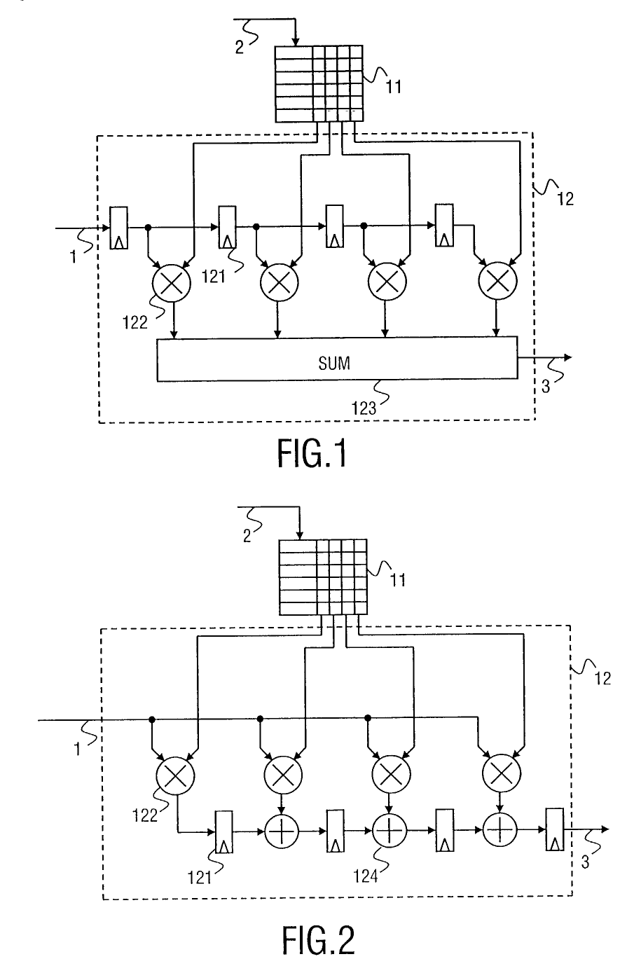

FIG. 5 is a diagram depicting the functioning in direct mode of a filter with 4 coefficients according to the invention. The polyphase filter first of all comprises selection means PSEL (51) able to select the polynomials according to the phase differences (2) between the input pixels and the output pixel. The coefficients of the selected polynomials are then stored in a memory MEM (52). The polyphase filter then comprises calculation means P1 to P4 (53) able to calculate a set of filtering coefficients from coefficients of the polynomials for the various phase differences (2). For example, for the phase differences φ1 to φ4 depicted in FIG. 4, 4 filtering coefficients c1 to c4 are determined by the calculation means. A filtering coefficient is calculated from the phase difference between the output pixel and one of the input pixels. Not all the polynomials are therefore necessarily used on each occasion, in particular when there is a large reduction in the format of the image. A convoluter as described in FIG. 1 then converts a digital input signal (1) sampled at a first frequency into a digital output signal (3) sampled at a second frequency using filtering coefficients thus calculated on the fly.

In addition to the fine adjustment of the dimension of an image, the conversion method and device according to the invention can be used with variable zoom factors, for example in order to convert an image from a 16/9 format to a 4/3 format. With each pixel of the image there is associated a horizontal and vertical zoom factor, the zoom factors being able to differ from one pixel to another. Thus, in order to convert an image from a 16/9 format to a 4/3 format, the horizontal zoom factors of the pixels situated in a central area of the image are close to 1 and the horizontal zoom factors of the pixels situated towards the edges of images are higher. In this way, the image is relatively little deformed and there is relatively little loss of information. It is also possible to take advantage of the variable zoom factors in order to correct other geometric defects such as, for example, a trapezoidal distortion.

The present invention also relates to a method of converting a digital input signal into a digital output signal from a set of filtering coefficients. Said method comprises a filtering step using a filtering function, intended to produce the set of filtering coefficients from phase differences between a sample of the digital output signal and samples of the digital input signal, the filtering function being defined by a set of polynomials. The filtering step also comprises a storage substep intended to store coefficients of the polynomials, and a calculation substep intended to calculate the set of filtering coefficients from coefficients of the polynomials and phase differences.

No reference sign between parentheses in the present text should be interpreted limitingly. The verb “comprise” and its conjugations should also be interpreted broadly, that is to say as not excluding the presence not only of elements or steps other than those after said verb, but also a plurality of elements or steps already listed after said verb and preceded by the word “a” or “an”.

1. A converter for converting a digital input signal (1) into a digital output signal (3) using a set of filtering coefficients, said converter comprising filtering means able to effect a filtering function and to produce a filtering coefficient from a phase difference (2) between a sample of the digital output signal and a sample of the digital input signal, characterized in that the filtering function is defined by a set of polynomials, and in that the filtering means comprise a memory (52) able to store coefficients of the polynomials, and calculation means (53) able to calculate the set of filtering coefficients from coefficients of the polynomials and phase differences between a sample of the digital output signal and samples of the digital input signal.

2. A converter for converting a digital input signal (1) as claimed in claim 1, characterized in that it comprises selection means (51) able to select the polynomials according to the phase differences (2) between samples of the digital input signal and a sample of the digital output signal.

3. A method of converting a digital input signal (1) into a digital output signal (3) using a set of filtering coefficients, said method comprising a filtering step using a filtering function and intended to produce a filtering coefficient from a phase difference (2) between a sample of the digital output signal and a sample of the digital input signal, characterized in that the filtering function is defined by a set of polynomials, and in that the filtering step comprises a storage substep intended to store coefficients of the polynomials, and a calculation substep intended to calculate the set of filtering coefficients from coefficients of the polynomials and phase differences between a sample of the digital output signal and samples of the digital input signal.

4. A method of converting a digital input signal (1) as claimed in claim 3, characterized in that it comprises a step of selecting polynomials according to phase differences (2) between samples of the digital input signal and a sample of the digital output signal.

5. A video monitor comprising a converter as claimed in claim 1.
